(19) United States
(12) Patent Application Publication
(10) Pub. No.: US 2026/0190917 A1
(43) Pub. Date: Jul. 2, 2026

(54) SUBSTRATE PROCESSING SYSTEM AND SUBSTRATE PROCESSING APPARATUS

(71) Applicant: Tokyo Electron Limited, Tokyo (JP)

(72) Inventor: Norihiko AMIKURA, Miyagi (JP)

(73) Assignee: Tokyo Electron Limited, Tokyo (JP)

(21) Appl. No.: 19/548,968

(22) Filed: Feb. 25, 2026

Related U.S. Application Data
(63) Continuation of application No. PCT/JP2024/025748, filed on Jul. 18, 2024.

(30) Foreign Application Priority Data
Sep. 6, 2023 (JP) 2023-144678

(51) Int. Cl. H10P 72/00; H01J 37/32; H10P 72/72

(52) U.S. Cl. CPC H10P 72/0462; H01J 37/32458; H01J 37/32715; H01J 37/32834; H10P 72/72; H01J 37/32091; H01J 2237/2007

(57) ABSTRACT

A substrate processing system including: a vacuum transfer structure; a main interface structure having a first surface connected to the vacuum transfer structure, a second surface on a side opposite to the first surface, an upper surface, and a lower surface; and a substrate processing module, wherein the substrate processing module includes a replaceable intermediate chamber structure having an upper surface and a lower surface, a replaceable upper chamber structure detachably connected to the upper surface of the replaceable intermediate chamber structure, and a replaceable lower chamber structure detachably connected to the lower surface of the replaceable intermediate chamber structure, the replaceable intermediate chamber structure includes a chamber sidewall structure defining an interior space, a substrate support located in the interior space, and an intermediate interface structure detachably connected to the second surface of the main interface structure.

### CROSS-REFERENCE TO RELATED APPLICATIONS

This application is a bypass continuation application of international application No. PCT/JP2024/025748 having an international filing date of Jul. 18, 2024 and designating the United States, the international application being based upon and claiming the benefit of priority from Japanese Patent Application No. 2023-144678, filed on Sep. 6, 2023, the entire contents of each of which are incorporated herein by reference.

### TECHNICAL FIELD

The present disclosure relates to a substrate processing system and a substrate processing apparatus.

### BACKGROUND

PTL 1 discloses a substrate processing system provided with a vacuum transfer module in which process modules are located on a side surface. An electrical unit is provided at an upper portion of a process module, and a power source system unit is provided at a lower portion of the process module.

### CITATION LIST

### Patent Documents

PTL 1: JP2021-034495A

### SUMMARY

The technique according to the present disclosure appropriately performs maintenance of a substrate processing module in a substrate processing system.

An aspect of the present disclosure is a substrate processing system including: a vacuum transfer structure; a main interface structure having a first surface connected to the vacuum transfer structure, a second surface on a side opposite to the first surface, an upper surface, and a lower surface; and a substrate processing module, wherein the substrate processing module includes a replaceable intermediate chamber structure having an upper surface and a lower surface, a replaceable upper chamber structure detachably connected to the upper surface of the replaceable intermediate chamber structure, and a replaceable lower chamber structure detachably connected to the lower surface of the replaceable intermediate chamber structure, the replaceable intermediate chamber structure includes a chamber sidewall structure defining an interior space, a substrate support located in the interior space, and an intermediate interface structure detachably connected to the second surface of the main interface structure, the replaceable upper chamber structure includes a chamber upper wall structure defining the interior space and having a gas introduction port to introduce a processing gas into the interior space, and an upper interface structure detachably connected to the upper surface of the main interface structure, and the replaceable lower chamber structure includes a chamber bottom wall structure defining the interior space and having a gas exhaust port to exhaust a gas in the interior space, and a lower interface structure detachably connected to the lower surface of the main interface structure.

According to the present disclosure, the maintenance of the substrate processing module can be appropriately performed in the substrate processing system.

### BRIEF DESCRIPTION OF DRAWINGS

The scope of the present disclosure is best understood from the following detailed description of exemplary embodiments when read in conjunction with the accompanying drawings.

FIG. 1 is a plan view illustrating a configuration of a substrate processing system according to an embodiment.

FIG. 2 is a perspective view illustrating a partial configuration of the substrate processing system according to the embodiment.

FIG. 3 is a perspective view illustrating a configuration of each unit according to the embodiment.

FIG. 4 is a perspective view illustrating an example of a state where an intermediate unit is attached to a main interface unit.

FIG. 5 is a perspective view illustrating an example of a state where an upper unit and a lower unit are attached to the main interface unit.

FIG. 6 is a diagram illustrating a configuration of a substrate processing module according to a first embodiment.

FIG. 7 is a diagram illustrating a configuration of each unit according to the first embodiment.

FIG. 8 is a diagram illustrating a configuration of a substrate processing module according to a second embodiment.

FIG. 9 is a diagram illustrating a configuration of each unit according to the second embodiment.

FIG. 10 is a diagram illustrating a configuration of a substrate processing module according to a third embodiment.

FIG. 11 is a diagram illustrating a configuration of each unit according to the third embodiment.

### DETAILED DESCRIPTION

In a process of manufacturing a semiconductor device, various processing steps of bringing a substrate processing module accommodating a semiconductor wafer (hereinafter referred to as a “substrate”) into a pressure-reduced state, and performing predetermined processing on the substrate are performed. The processing steps are performed using, for example, a substrate processing apparatus in which the substrate processing modules are located around a common transfer module.

As disclosed in PTL 1, a substrate processing module includes many components related to an interior space, a gas supply system, a power source system, or a control system for performing processing on a substrate. Maintenance such as initial preparation, inspection, cleaning, repair, replacement, or the like is performed on these components as necessary.

However, in the substrate processing system disclosed in PTL 1, the entire substrate processing module may need to be removed or disassembled when the substrate processing module is maintained. In this case, productivity of the entire substrate processing system may deteriorate while the substrate processing module cannot be used. When the substrate processing module is first provided in the substrate processing system or provided again after the maintenance, it is necessary to individually connect pipes, cables, and the like related to the gas supply system, the power source system, or the control system described above. In a case of transferring the entire substrate processing module between the substrate processing system and an outside, costs are required for the transfer. It also requires costs to store the entire replacement substrate processing module outside. Therefore, there is room for improvement in terms of performing the maintenance appropriately.

Therefore, in the technique according to the present disclosure, the maintenance of the substrate processing module is appropriately performed in the substrate processing system. Specifically, a substrate processing system including units capable of appropriately performing maintenance is provided.

Hereinafter, a configuration of a substrate processing apparatus according to the present embodiment will be described with reference to the drawings. The same reference numerals will be given to elements having substantially the same functional configurations throughout the specification, and redundant description thereof will be omitted.

### Substrate Processing System

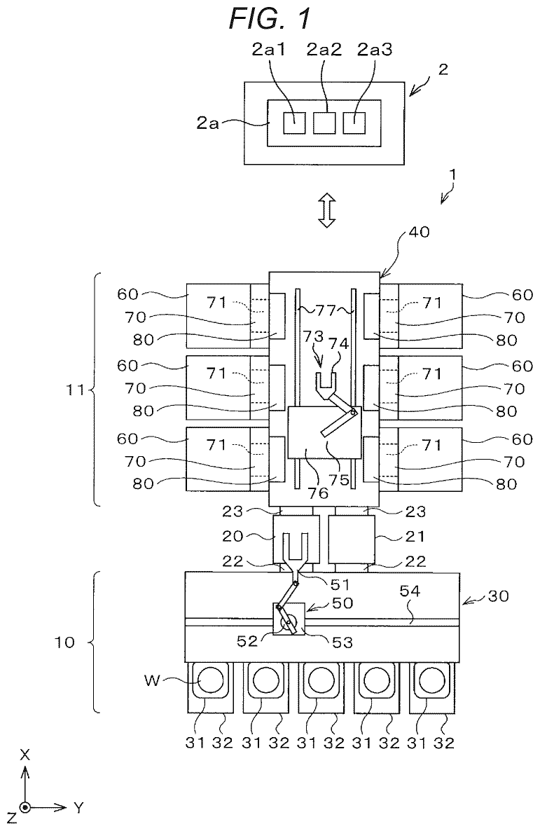

A substrate processing system according to the present embodiment will be described. FIG. 1 is a plan view illustrating a schematic configuration of the substrate processing system according to the present embodiment. In the substrate processing system, processes including desired gas processing such as film formation processing, cleaning processing, and other plasma processing are performed on a substrate W (herein “film” means the same as “layer”).

As illustrated in FIG. 1, the substrate processing system includes a substrate processing apparatus 1 and a controller 2 (herein “controller” means the same as “controller circuitry”). The substrate processing apparatus 1 has a configuration in which an atmospheric unit 10 and a decompression unit 11 are integrally connected to each other via load-lock modules 20 and 21. The atmospheric unit 10 includes an atmospheric module that performs desired processing on a substrate W under an atmospheric pressure atmosphere. The decompression unit 11 includes a decompression module that performs desired processing on the substrate W in a vacuum environment.

The load-lock modules 20 and 21 are provided to be connected to an atmospheric transfer module 30 to be described later of the atmospheric unit 10 and a vacuum transfer module 40 to be described later of the decompression unit 11 via gate valves 22 and 23 (herein “vacuum transfer module” means the same as “vacuum transfer structure”). The load-lock modules 20 and 21 are configured to temporarily hold the substrate W. Further, each of the load lock modules 20 and 21 is configured such that an inner space thereof can be switched between an atmospheric pressure atmosphere and a pressure-reduced atmosphere (vacuum atmosphere).

The atmospheric unit 10 includes the atmospheric transfer module 30 provided with a substrate transfer mechanism 50 to be described later, and load ports 32 on which hoops 31 capable of storing the substrates W are placed. An orienter module that adjusts an orientation of the substrate W in a horizontal direction, a storage module that stores the substrates W, and the like may be provided adjacent to the atmospheric transfer module 30.

The atmospheric transfer module 30 includes a substantially rectangular parallelepiped-shaped housing therein, and an interior of the housing is maintained at the atmospheric pressure atmosphere. A plurality of load ports 32, for example, five load ports 32, are located in parallel on one side surface forming a long side of the housing of the atmospheric transfer module 30. The load-lock modules 20 and 21 are located in parallel on the other side surface forming the long side of the housing of the atmospheric transfer module 30.

The substrate transfer mechanism 50 that transfers the substrate W is provided inside the atmospheric transfer module 30. The substrate transfer mechanism 50 includes a transfer arm 51 that holds and moves the substrate W, a rotation table 52 that rotatably supports the transfer arm 51, and a rotation stage 53 on which the rotation table 52 is placed. A guide rail 54 extending in a longitudinal direction of the atmospheric transfer module 30 is provided inside the atmospheric transfer module 30. The rotation stage 53 is located on the guide rail 54, and the substrate transfer mechanism 50 is configured to be movable along the guide rail 54.

The decompression unit 11 includes the vacuum transfer module 40 that transfers the substrate W therein, and substrate processing modules 60 each performing desired processing on the substrate W transferred from the vacuum transfer module 40. The vacuum transfer module 40 and an interior of a chamber to be described later in the substrate processing module 60 are configured to be maintained in the vacuum environment.

The substrate processing modules 60 are connected to one vacuum transfer module 40. The chamber of the substrate processing module 60 is connected to the vacuum transfer module 40 via an opening 71 provided in a main interface unit 70 (herein “main interface unit” means the same as “main interface structure”). The opening 71 includes at least one gate valve. Details of the substrate processing module 60 and the main interface unit 70 will be described later. In the example illustrated in FIG. 1, six substrate processing modules 60 are connected. However, the present disclosure is not limited thereto, and fewer or more than six substrate processing modules 60 may be connected.

The vacuum transfer module 40 is connected to the load-lock modules 20 and 21 as described above. In one embodiment, the vacuum transfer module 40 is configured to transfer the substrate W (that was transferred from the atmospheric unit 10 to the load-lock module 20) to one of the substrate processing modules 60. That is the vacuum transfer module 40 transfers the substrate from the load-lock module 40 to one of the substrate processing modules. The vacuum transfer module 40 is also configured to transfer the substrate W subjected to the desired processing in the substrate processing module 60 to the load-lock module 21.

A substrate transfer mechanism 73 that transfers the substrate W is provided inside the vacuum transfer module 40. The substrate transfer mechanism 73 includes a transfer arm 74 that holds and moves the substrate W, a rotation table 75 that rotatably supports the transfer arm 74, and a rotation stage 76 on which the rotation table 75 is placed. A guide rail 77 extending in a longitudinal direction of the vacuum transfer module 40 is provided inside the vacuum transfer module 40. The rotation stage 76 is located on the guide rail 77, and the substrate transfer mechanism 73 is configured to be movable along the guide rail 77.

The substrate transfer mechanism 73 receives the substrate W held by the load-lock module 20 by the transfer arm 74 and transfers the substrate W to a desired substrate processing module 60. The substrate transfer mechanism 73 holds the substrate W subjected to the desired processing in the substrate processing module 60 by the transfer arm 74, and transfers the substrate W to the load-lock module 21.

The vacuum transfer module 40 is further provided with gas boxes 80, for example, corresponding to the substrate processing modules 60 in the present embodiment, that supply gases to the substrate processing modules 60. The gas box 80 is an example of a gas box unit (herein “gas box unit” means the same as “gas box structure.”). The number and arrangement of the gas boxes 80 are not limited to the present embodiment. In the example illustrated in FIG. 1, six gas boxes 80 are provided corresponding to the six substrate processing modules 60. However, the present disclosure is not limited thereto, and fewer or more than six gas boxes 80 may be provided. The gas box 80 according to one embodiment is attached to a frame of the substrate processing module 60 to be located above the vacuum transfer module 40.

The controller 2 processes computer-executable instructions for instructing the substrate processing apparatus 1 to execute various steps described in the present disclosure. The controller 2 may be configured to control each element of the substrate processing apparatus 1 to execute the various steps described herein below. In an embodiment, part or all of the controller 2 may be included in the substrate processing apparatus 1. The controller 2 may include a processor 2a1, a storage 2a2, and a communication interface 2a3. The controller 2 is implemented, for example, by a computer 2a. The processor 2a1 may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various recording media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the substrate processing apparatus 1 via a communication line such as a local area network (LAN). The controller/controller circuitry 2 can be programmable circuitry (e.g., embedded processor) or fixed circuitry (e.g., ASIC or PAL). In an exemplary embodiment, the controller/controller circuitry 2 can include one or more programmable processors/controllers.

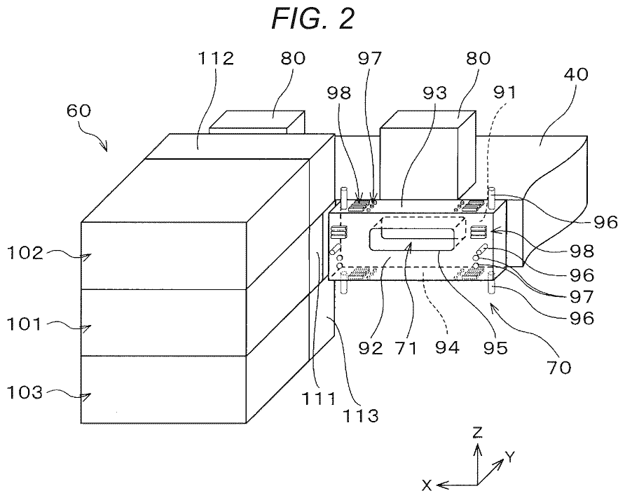

FIG. 2 is a perspective view schematically illustrating a partial schematic configuration of the substrate processing system according to the present embodiment. The main interface unit 70 has a first surface 91 located on a side (a Y-axis positive direction side) of the main interface unit 70 connected to the vacuum transfer module 40, a second surface 92 located on a side (a Y-axis negative direction side) opposite to the first surface 91, a third surface 93 located on an upper side (a Z-axis positive direction side) between the first surface 91 and the second surface 92, and a fourth surface 94 located on a lower side (a Z-axis negative direction side) between the first surface 91 and the second surface 92. The opening 71 is provided to extend from the first surface 91 to the second surface 92. A seal ring 95 is provided in the opening 71 on a second surface 92 side.

The second surface 92, the third surface 93, and the fourth surface 94 each have guide pins 96. The second surface 92, the third surface 93, and the fourth surface 94 each include one or more ports 97 or connectors 98.

As illustrated in FIG. 2, the substrate processing module 60 according to the present embodiment is detachably provided to the main interface unit 70. The substrate processing module 60 is attached to the main interface unit 70 on a left side (an X-axis positive direction side) in FIG. 2, and the substrate processing module 60 is removed from the main interface unit 70 on a right side (a X-axis negative direction side) in the drawing.

The substrate processing module 60 includes at least an intermediate unit 101, an upper unit 102, and a lower unit 103. The intermediate unit 101, the upper unit 102, and the lower unit 103 are examples of a replaceable intermediate chamber unit, a replaceable upper chamber unit, and a replaceable lower chamber unit, respectively (herein “replaceable intermediate chamber unit,” “replaceable upper chamber unit,” and “replaceable lower chamber unit” mean the same as “replaceable intermediate chamber structure,” “replaceable upper chamber structure,” and “replaceable lower chamber structure,” respectively). The intermediate unit 101 includes an intermediate interface structure 111. The intermediate unit 101 is detachably attached to the second surface 92 of the main interface unit 70 via the intermediate interface structure 111. The upper unit 102 includes an upper interface structure 112, and is detachably attached to the third surface 93 of the main interface unit 70 via the upper interface structure 112. The lower unit 103 includes a lower interface structure 113, and is detachably attached to the fourth surface 94 of the main interface unit 70 via the lower interface structure 113.

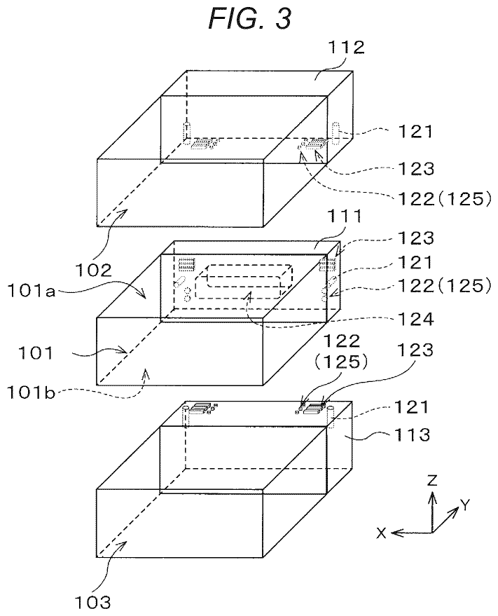

FIG. 3 is a schematic diagram illustrating a schematic configuration of the intermediate unit 101, the upper unit 102, and the lower unit 103 in a state of being removed from the main interface unit 70. In FIG. 3, only structures on outer surfaces of housings of the intermediate interface structure 111, the upper interface structure 112, and the lower interface structure 113 are illustrated. Illustrations of interiors of these structures, internal structures of the respective units other than these structures, and the like are omitted. The intermediate unit 101, the upper unit 102, and the lower unit 103 are detachable from each other and may be separated from each other as illustrated in FIG. 3. The intermediate unit 101 has an upper surface 101a and a lower surface 101b, and is detachable from the upper unit 102 at the upper surface 101a and detachable from the lower unit 103 at the lower surface 101b.

The intermediate interface structure 111 of the intermediate unit 101 has guide holes 121 at positions corresponding to the guide pins 96 provided on the second surface 92 of the main interface unit 70. Ports 122 and connectors 123 are provided at positions corresponding to the ports 97 and the connectors 98 provided in the second surface 92. An opening 124 is provided at a position corresponding to the opening 71 in the second surface 92. The opening 124 is provided to penetrate from a surface (a surface on the Y-axis positive direction side) of the intermediate interface structure 111 that faces the second surface 92 to a surface on the opposite side (a surface on the Y-axis negative direction side). The port 122 is provided with a seal ring 125.

Similarly, each of the upper unit 102 and the lower unit 103 includes the guide holes 121, the ports 122, and the connectors 123 at positions corresponding to the guide pins 96, the ports 97, and the connectors 98 provided on the third surface 93 and the fourth surface 94. The port 122 is provided with the seal ring 125.

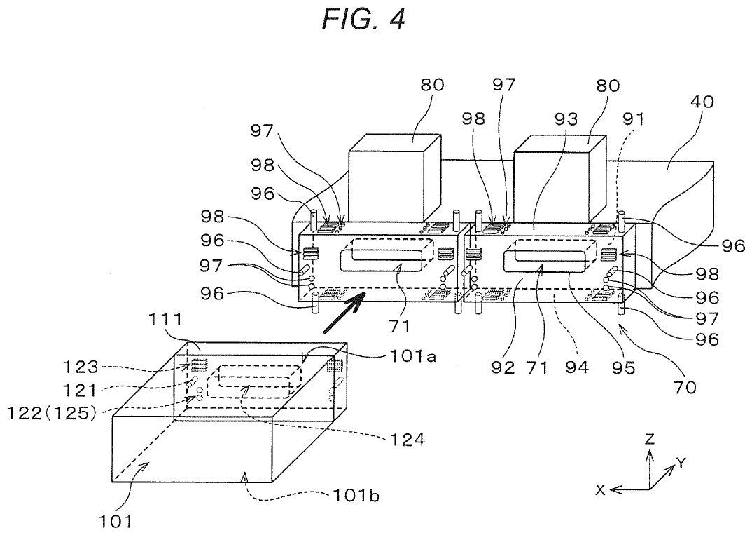

In one embodiment, from a state where the intermediate unit 101, the upper unit 102, and the lower unit 103 of the substrate processing module 60 are removed from each other, the intermediate unit 101 is first attached to the main interface unit 70. FIG. 4 is a perspective view illustrating an example of a state where the intermediate unit 101 is to be attached to the main interface unit 70. In the example of FIG. 4, the intermediate unit 101 is moved from the Y-axis negative direction side toward a positive direction side such that the guide holes 121 provided in the intermediate interface structure 111 are fitted into the guide pins 96 provided in the second surface 92 of the main interface unit 70. The main interface unit 70 and the intermediate interface structure 111 are fastened to each other in a state where the second surface 92 and the surface (the surface on the Y-axis positive direction side) of the intermediate interface structure 111 that faces the second surface 92 are in contact with each other. A fastening method is not particularly limited, and may be known clamps or bolts.

In a state where the second surface 92 of the main interface unit 70 and the intermediate interface structure 111 are fastened to each other, the opening 71 in the second surface 92 and the opening 124 in the intermediate interface structure 111 are in contact with each other, and these openings are connected to each other in a state of being sealed from outside air by the seal ring 95. The vacuum transfer module 40 communicates with a chamber 200 to be described later via the connected openings 71 and openings 124. The substrate W is transferred between the vacuum transfer module 40 and the chamber 200 by the transfer arm 74 through the opening 71 and the opening 124.

The ports 97 in the second surface 92 and the ports 122 of the intermediate interface structure 111 are in contact with each other, and these openings are connected in a state of being sealed from the outside air by the seal ring 125. The connectors 98 on the second surface 92 and the connectors 123 of the intermediate interface structure 111 are in contact with each other and connected to each other.

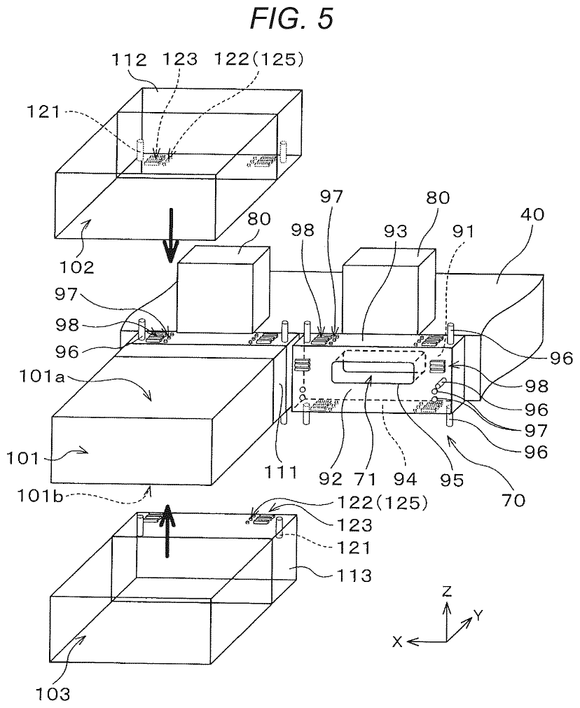

Next, in the state where the second surface 92 of the main interface unit 70 and the intermediate interface structure 111 are fastened to each other, the upper unit 102 and the lower unit 103 are attached to the main interface unit 70. FIG. 5 is a perspective view illustrating an example of a state where the upper unit 102 and the lower unit 103 are to be attached to the main interface unit 70. In the example of FIG. 5, for the upper unit 102, the upper unit 102 is moved from the Z-axis positive direction side toward a negative direction side such that the guide holes 121 provided in the upper interface structure 112 are fitted into the guide pins 96 provided in the third surface 93 of the main interface unit 70. The main interface unit 70 and the upper interface structure 112 are fastened to each other in a state where the third surface 93 and a surface (a surface on the Z-axis negative direction side) of the upper interface structure 112 that faces the third surface 93 are in contact with each other. Similarly, even for the lower unit 103, the lower unit 103 is moved from the Z-axis negative direction side toward the positive direction side such that the guide holes 121 provided in the lower interface structure 113 are fitted into the guide pins 96 provided in the fourth surface 94 of the main interface unit 70. The main interface unit 70 and the lower interface structure 113 are fastened to each other in a state where the fourth surface 94 and a surface (a surface on the Z-axis positive direction side) of the lower interface structure 113 that faces the fourth surface 94 are in contact with each other. A fastening method is not particularly limited, and may be known clamp mechanisms or bolts.

In a state where the third surface 93 of the main interface unit 70 and the upper unit 102 are fastened to each other, the ports 97 in the third surface 93 and the ports 122 of the upper interface structure 112 are in contact with each other, and these ports are connected to each other in a state of being sealed from the outside air by the seal ring 125. The connectors 98 in the third surface 93 and the connectors 123 of the upper interface structure 112 are in contact with each other and connected to each other. Similarly, in a state where the fourth surface 94 of the main interface unit 70 and the lower unit 103 are fastened to each other, the ports 97 in the fourth surface 94 and the ports 122 of the lower interface structure 113 are in contact with each other, and these ports are connected to each other in a state of being sealed from the outside air by the seal ring 125. The connectors 98 in the fourth surface 94 and the connectors 123 of the lower interface structure 113 are in contact with each other and connected to each other.

An example of a state where the intermediate unit 101, the upper unit 102, and the lower unit 103 are attached to the main interface unit 70 is as illustrated in FIG. 2.

### SUBSTRATE PROCESSING MODULE

### First Embodiment

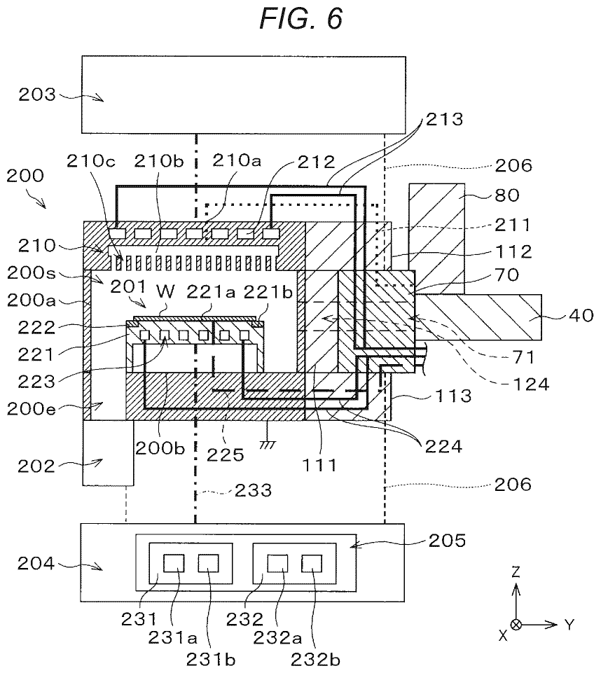

FIG. 6 is a view illustrating an example of a configuration of the substrate processing module 60 according to a first embodiment. FIG. 6 is a cross-sectional view of the substrate processing module 60 in the state where the intermediate unit 101, the upper unit 102, and the lower unit 103 are attached to the main interface unit 70. The substrate processing module 60 according to the present embodiment implements a capacitively-coupled plasma processing apparatus. The substrate processing module 60 includes a plasma processing chamber 200 (hereinafter, referred to as the chamber 200), a substrate support 201, and a plasma generator. The substrate processing module 60 has a plasma processing space 200s, which is an interior space of the chamber 200. The chamber 200 has at least one gas supply port for supplying at least one processing gas from the gas box 80 to the plasma processing space 200s, and at least one gas exhaust port for exhausting a gas from the plasma processing space 200s. The gas supply port is connected to the gas box 80, and the gas exhaust port is connected to an exhaust system 202 to be described later. The substrate support 201 is located in the plasma processing space 200s and has a substrate support surface for supporting the substrate.

The substrate processing module 60 includes an upper box 203 located at an upper portion of the chamber 200 and a lower box 204 located at a lower portion of the chamber 200. In one embodiment, various devices such as an electrical unit configured to control the substrate processing module 60 may be located in the upper box 203 (herein “electrical unit” means the same as “electrical circuitry unit”). In one embodiment, a power source 205 that supplies power to the substrate processing module 60 is located in the lower box 204.

The electrical unit that controls the substrate processing module 60 and is provided in the upper box 203 transmits and receives signals to and from the chamber 200 and the lower box 204 via a signal cable 206. The signal cable 206 is connected from the upper box 203 to the chamber 200 via the upper interface structure 112, the main interface unit 70, and the intermediate interface structure 111. That is, the connectors 123 of the upper interface structure 112, the connectors 98 of the main interface unit 70, and the connectors 123 of the intermediate interface structure 111 include connectors on a path of the signal cable 206. The signal cable 206 is connected from the upper box 203 to the chamber 200 via the upper interface structure 112, the main interface unit 70, and the lower interface structure 113. That is, the connectors 123 of the lower interface structure 113 include connectors on the path of the signal cable 206.

The plasma generator is configured to generate a plasma from at least one processing gas supplied into the plasma processing space 200s. The plasma formed in the plasma processing space 200s may be capacitively coupled plasma (CCP), inductively coupled plasma (ICP), electron-cyclotron-resonance plasma (ECR plasma), helicon wave plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The gas box 80 may include at least one gas source and at least one flow rate controller. In one embodiment, the gas box 80 is configured to supply at least one processing gas from each corresponding gas source to a shower head 210 via each corresponding flow rate controller. Each flow rate controller may include, for example, a mass flow controller or a flow rate controller of a pressure control type. The gas box 80 may include at least one flow rate modulation device that modulates or pulses a flow rate of the at least one processing gas.

The gas is supplied from the gas box 80 to the shower head 210 via a flow path 211 indicated by a thick dotted line in FIG. 6. The flow path 211 is provided from the gas box 80 to pass through the main interface unit 70 and the upper interface structure 112. That is, the ports 97 of the main interface unit 70 and the ports 122 of the upper interface structure 112 include ports in the flow path 211.

The substrate processing module 60 includes a gas introduction unit. The gas introduction unit is configured to introduce the at least one processing gas supplied from the gas box 80 into the chamber 200. The gas introduction unit includes the shower head 210. The shower head 210 is located above the substrate support 201. The substrate support 201 is located in the chamber 200 and is fixed on a bottom wall 200b. The shower head 210 constitutes at least a part of a chamber upper wall structure as a ceiling portion of the chamber 200. The plasma processing space 200s is defined by the shower head 210 serving as the chamber upper wall structure, a sidewall 200a serving as a chamber sidewall structure, and the bottom wall 200b serving as a chamber bottom wall structure. The chamber 200 is grounded. The shower head 210 and the substrate support 201 are electrically insulated from a housing of the chamber 200.

The shower head 210 includes at least one gas supply port 210a, at least one gas diffusion chamber 210b, and gas introduction ports 210c. The processing gas supplied to the gas supply port 210a passes through the gas diffusion chamber 210b and is introduced into the plasma processing space 200s from the gas introduction ports 210c. The shower head 210 includes at least one upper electrode. The gas introduction unit may include, in addition to the shower head 210, one or more side gas injectors (SGI) that are attached to one or more openings formed in the sidewall 200a.

The shower head 210 includes a flow path 212. A heat transfer fluid, such as brine or a gas, flows through the flow path 212. The heat transfer fluid is supplied from a heat transfer fluid supply or is exhausted to the heat transfer fluid supply from the flow path 212. The supply of the heat transfer fluid from the heat transfer fluid supply or the exhausting of the heat transfer fluid to the heat transfer fluid supply is performed via a flow path 213 indicated by a thick solid line in FIG. 6. The flow path 213 is provided from the heat transfer fluid supply to pass through the main interface unit 70 and the upper interface structure 112. That is, the ports 97 of the main interface unit 70 and the ports 122 of the upper interface structure 112 include ports of the flow path 213.

The substrate support 201 includes a main body 221 and a ring assembly 222. The main body 221 has a central region 221a for supporting the substrate W and an annular region 221b for supporting the ring assembly 222. A wafer is an example of the substrate W. The annular region 221b of the main body 221 surrounds the central region 221a of the main body 221 in a plan view. The substrate W is located on the central region 221a of the main body 221. The ring assembly 222 is located on the annular region 221b of the main body 221 to surround the substrate W on the central region 221a of the main body 221. Therefore, the central region 221a is also called a substrate support surface for supporting the substrate W, and the annular region 221b is also called a ring support surface for supporting the ring assembly 222.

In one embodiment, the main body 221 includes a base and an electrostatic chuck. The base includes a conductive member. The conductive member of the base may function as a lower electrode. The electrostatic chuck is located on the base. The electrostatic chuck includes a ceramic member and an electrostatic electrode located in the ceramic member. The ceramic member has the central region 221a. In one embodiment, the ceramic member also has the annular region 221b. Other members that surround the electrostatic chuck, such as an annular electrostatic chuck and an annular insulating member, may have the annular region 221b. In this case, the ring assembly 222 may be located on the annular electrostatic chuck or the annular insulating member, or may be located on both the annular electrostatic chuck and the annular insulating member. At least one RF/DC electrode coupled to an RF power source 231 and/or a DC power source 232 to be described later may be located in the ceramic member. In this case, at least one RF/DC electrode functions as the lower electrode. In a case where a bias RF signal and/or a DC signal to be described later are supplied to at least one RF/DC electrode, the RF/DC electrode is also referred to as a bias electrode. The conductive member of the base and at least one RF/DC electrode may function as a plurality of lower electrodes. Further, the electrostatic electrode may function as the lower electrode. Therefore, the substrate support 201 includes at least one lower electrode. In one embodiment, the above-described electrical unit includes a chuck power source configured to apply a chuck voltage to the electrostatic electrode. In another embodiment, an RF unit to be described later includes the chuck power source configured to apply the chuck voltage to the electrostatic electrode.

The ring assembly 222 includes one or more annular members. In one embodiment, the one or more annular members include one or more edge rings and at least one cover ring. The edge ring is made of an electrically conductive material or an insulating material, and the cover ring is made of an insulating material.

The substrate support 201 may include a temperature control module configured to adjust at least one of the electrostatic chuck, the ring assembly 222, and the substrate W to a target temperature. The temperature control module may include a heater, a heat transfer medium, a flow path 223, or a combination thereof. A heat transfer fluid, such as brine or a gas, flows through the flow path 223. The heat transfer fluid is supplied from a heat transfer fluid supply or is exhausted to the heat transfer fluid supply from the flow path 223. The supply of the heat transfer fluid from the heat transfer fluid supply or the exhausting of the heat transfer fluid to the heat transfer fluid supply is performed via a flow path 224 indicated by a thick solid line in FIG. 6. In one embodiment, the flow path 223 is formed inside the base, and one or more heaters are located inside the ceramic member of the electrostatic chuck.

The substrate support 201 is configured to supply a heat transfer gas to a gap between a back surface of the substrate W and the central region 221a. The heat transfer gas is supplied from a heat transfer gas supply or is exhausted from the gap to the heat transfer gas supply. The supply and exhausting of the heat transfer gas from and to the heat transfer gas supply is performed via a flow path 225 indicated by a thick broken line in FIG. 6. The heat transfer gas contains, for example, an inert gas such as helium.

The flow path 224 and the flow path 225 are provided from the heat transfer fluid supply and the heat transfer gas supply to pass through the main interface unit 70 and the lower interface structure 113. That is, the ports 97 of the main interface unit 70 and the ports 122 of the lower interface structure 113 include ports in the flow path 224 and the flow path 225.

The power source 205 as an example of the RF unit according to the present embodiment includes the RF power source 231 coupled to the chamber 200 via at least one impedance matching circuit. The RF power source 231 is configured to supply at least one RF signal (RF power) to the at least one lower electrode and/or the at least one upper electrode. Accordingly, the plasma is formed from the at least one processing gas supplied to the plasma processing space 200s. Therefore, the RF power source 231 may function as at least a part of the plasma generator. Supplying the bias RF signal to at least one lower electrode can generate a bias potential in the substrate W to attract an ionic component in the formed plasma to the substrate W.

In one embodiment, the RF power source 231 includes a first RF generator 231a and a second RF generator 231b. The first RF generator 231a is coupled to the at least one lower electrode and/or the at least one upper electrode via the at least one impedance matching circuit, and is configured to generate a plasma generation source RF signal (source RF power). The source RF signal is supplied through a coaxial cable 233 illustrated by a thick dashed line in FIG. 6. In one embodiment, the source RF signal has a frequency within a range from 10 MHz to 150 MHz. In one embodiment, the first RF generator 231a may be configured to generate source RF signals having different frequencies. The generated one or more source RF signals are supplied to at least one lower electrode and/or at least one upper electrode.

The second RF generator 231b is coupled to the at least one lower electrode via the at least one impedance matching circuit, and is configured to generate the bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 231b may be configured to generate bias RF signals having different frequencies. The generated one or more bias RF signals are supplied to at least one lower electrode. In various embodiments, at least one of the source RF signal and the bias RF signal may be pulsed.

The power source 205 may also include the DC power source 232 coupled to the chamber 200. The DC power source 232 includes a first DC generator 232a and a second DC generator 232b. In one embodiment, the first DC generator 232a is connected to the at least one lower electrode, and is configured to generate a first DC signal. The generated first DC signal is applied to at least one lower electrode. In one embodiment, the second DC generator 232b is connected to the at least one upper electrode, and is configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one embodiment, a waveform generator for generating a sequence of voltage pulses from a DC signal is connected between the first DC generator 232a and the at least one lower electrode. Therefore, the first DC generator 232a and the waveform generator form a voltage pulse generator. When the second DC generator 232b and the waveform generator implement the voltage pulse generator, the voltage pulse generator is connected to the at least one upper electrode. The voltage pulse may have a positive polarity or a negative polarity. The sequence of the voltage pulses may include one or more positive voltage pulses and one or more negative voltage pulses in one cycle. The first and second DC generators 232a and 232b may be provided in addition to the RF power source 231, and the first DC generator 232a may be provided instead of the second RF generator 231b.

For example, the exhaust system 202 may be connected to a gas exhaust port 200e provided at a bottom of the chamber 200. The exhaust system 202 is an example of an exhaust unit according to the present embodiment, and constitutes at least a part of an exhaust line according to the present embodiment (herein “exhaust unit” means the same thing as “exhaust structure”). The exhaust system 202 may include a pressure adjusting valve and a vacuum pump. The pressure adjusting valve adjusts a pressure in the plasma processing space 200s. The vacuum pump may include a turbo molecular pump, a dry pump, or a combination thereof.

### Intermediate Unit 101, Upper Unit 102, and Lower Unit 103

Hereinafter, the configurations of the intermediate unit 101, the upper unit 102, and the lower unit 103 in the substrate processing module 60 according to the first embodiment will be described. As described above, the substrate processing module 60 includes at least the intermediate unit 101, the upper unit 102, and the lower unit 103, which are detachably attached to the main interface unit 70. The intermediate unit 101, the upper unit 102, and the lower unit 103 are detachable from each other.

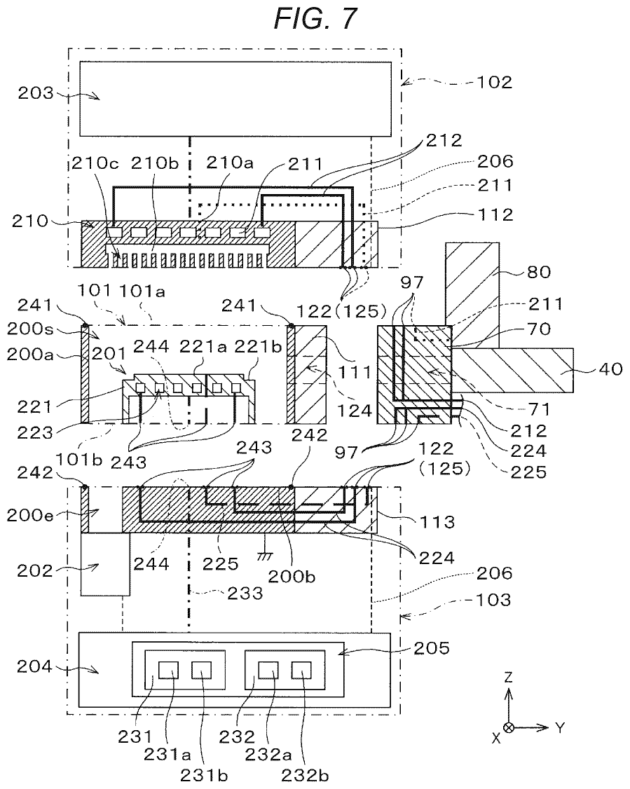

FIG. 7 is a view illustrating a configuration example of the intermediate unit 101, the upper unit 102, and the lower unit 103 in the substrate processing module 60 according to the first embodiment. In FIG. 7, the substrate processing module 60 is removed from the main interface unit 70, and the intermediate unit 101, the upper unit 102, and the lower unit 103 are separated from each other.

The intermediate unit 101 includes the chamber sidewall 200a and the substrate support 201. The upper unit 102 includes the upper box 203 and the shower head 210. That is, in the present embodiment, the above-described electrical unit provided in the upper box 203 is included in the upper unit 102. The lower unit 103 includes the gas exhaust port 200e, the exhaust system 202, and the lower box 204. That is, in the present embodiment, the RF unit provided in the lower box 204 is included in the lower unit 103.

A seal ring 241 is provided on an upper surface of an outer periphery of the chamber sidewall 200a of the intermediate unit 101. When the intermediate unit 101 and the upper unit 102 are fastened to each other, the chamber sidewall 200a and the shower head 210 are in contact with each other, and are connected to each other in a state of being sealed from the outside air by the seal ring 241. A seal ring 242 is provided at a position corresponding to a lower surface of the chamber sidewall 200a on the outer peripheral upper surface of a housing of the lower unit 103. When the intermediate unit 101 and the lower unit 103 are fastened to each other, the chamber sidewall 200a and the housing of the lower unit 103 are in contact with each other, and are connected to each other in a state of being sealed from the outside air by the seal ring 242.

The lower unit 103 is provided with the seal ring 242 at a position corresponding to the lower surface of the chamber sidewall 200a. When the intermediate unit 101 and the lower unit 103 are fastened to each other, the chamber sidewall 200a and the housing of the lower unit 103 are in contact with each other, and are connected to each other in a state of being in which the intermediate unit 101 and the lower unit 103 are sealed from the outside air by the seal ring 242.

The flow path 224 and the flow path 225 have ports 243 in a lower surface of the intermediate unit 101 and an upper surface of the lower unit 103, and are divided in the respective ports 243 in a state where the intermediate unit 101 and the lower unit 103 are separated. The ports 243 in the upper surface of the lower unit 103 are provided with seal rings. When the intermediate unit 101 and the lower unit 103 are fastened to each other, the lower surface of the intermediate unit 101 and the upper surface of the lower unit 103 are in contact with each other, and the ports 243 in the flow path 224 and the flow path 225 are connected in a state of being sealed from the outside air by the seal rings.

The coaxial cable 233 includes connectors 244 in the lower surface of the intermediate unit 101 and the upper surface of the lower unit 103, and is divided by the connectors 244 in a state where the intermediate unit 101 and the lower unit 103 are separated from each other. When the intermediate unit 101 and the lower unit 103 are fastened to each other, the lower surface of the intermediate unit 101 and the upper surface of the lower unit 103 are in contact with each other, and the coaxial cable 233 is connected by the connectors 244.

### Second Embodiment

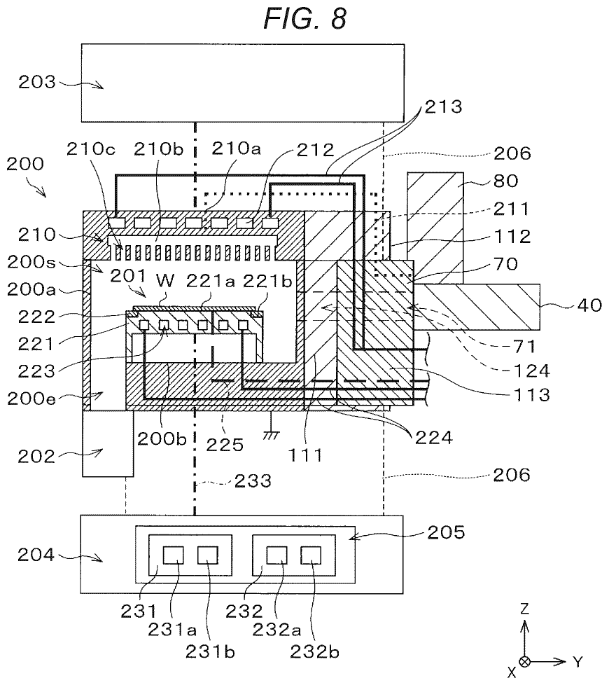

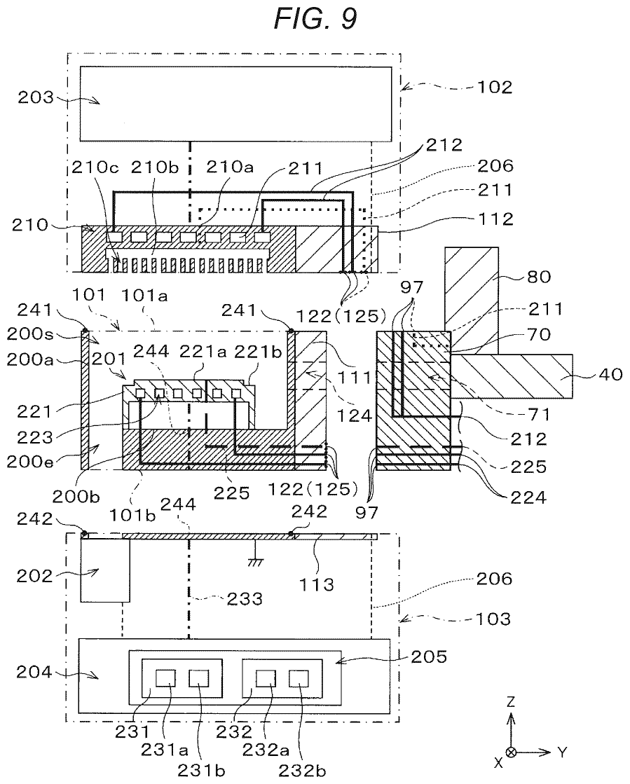

Hereinafter, configurations of the intermediate unit 101, the upper unit 102, and the lower unit 103 in the substrate processing module 60 according to a second embodiment will be described. FIGS. 8 and 9 are views illustrating configuration examples of the intermediate unit 101, the upper unit 102, and the lower unit 103 in the substrate processing module 60 according to the second embodiment. FIG. 8 illustrates a state where the individual units of the substrate processing module 60 are fastened and attached to the main interface unit 70. FIG. 9 illustrates a state where the substrate processing module 60 is removed from the main interface unit 70, and the intermediate unit 101, the upper unit 102, and the lower unit 103 are separated from each other.

The substrate processing module 60 according to the second embodiment differs from that according to the first embodiment in the configurations of the intermediate unit 101 and the lower unit 103. The intermediate unit 101 includes the chamber sidewall 200a, the gas exhaust port 200e, and the substrate support 201. The lower unit 103 includes the exhaust system 202 and the lower box 204. The configuration of the upper unit 102 is the same as that of the first embodiment.

In the intermediate unit 101 according to the second embodiment, the flow path 224 and the flow path 225 are provided from a heat transfer fluid supply and a heat transfer gas supply to pass through the main interface unit 70 and the intermediate interface structure 111. That is, the ports 97 of the main interface unit 70 and the ports 122 of the intermediate interface structure 111 include ports in the flow path 224 and the flow path 225.

### Third Embodiment

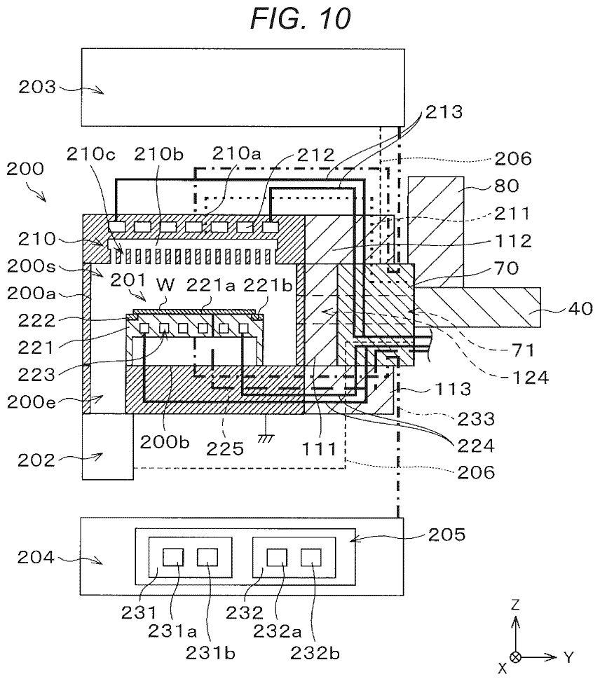

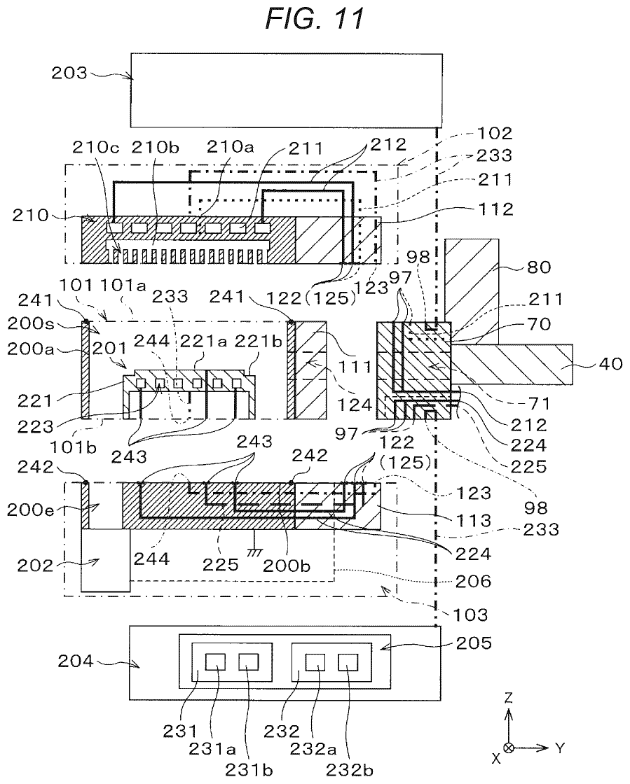

Hereinafter, configurations of the intermediate unit 101, the upper unit 102, and the lower unit 103 in the substrate processing module 60 according to a third embodiment will be described. FIGS. 10 and 11 are views illustrating configuration examples of the intermediate unit 101, the upper unit 102, and the lower unit 103 in the substrate processing module 60 according to the third embodiment. FIG. 10 illustrates a state where the individual units of the substrate processing module 60 are fastened and attached to the main interface unit 70. FIG. 11 illustrates a state where the substrate processing module 60 is removed from the main interface unit 70, and the intermediate unit 101, the upper unit 102, and the lower unit 103 are separated from each other.

The intermediate unit 101 according to the third embodiment includes the chamber sidewall 200a and the substrate support 201. The upper unit 102 includes the shower head 210. The lower unit 103 includes the gas exhaust port 200e and the exhaust system 202. In one embodiment, the upper box 203 including an electrical unit is attached to a frame of the substrate processing module 60 that is located above the upper unit 102. The lower box 204 including an RF unit is attached to the frame of the substrate processing module 60 that is located below the lower unit 103 (herein “RF unit” means the same as “RF circuitry unit”).

The coaxial cable 233 according to the third embodiment is connected from the upper box 203 to an upper electrode via the main interface unit 70 and the upper interface structure 112. That is, the connectors 98 of the main interface unit 70 and the connectors 123 of the upper interface structure 112 include connectors of the coaxial cable 233. The coaxial cable 233 is connected from the lower box 204 to a lower electrode via the main interface unit 70 and the lower interface structure 113. That is, the connectors 98 of the main interface unit 70 and the connectors 123 of the lower interface structure 113 include connectors of the coaxial cable 233.

A configuration for connecting the flow path 224 and the flow path 225 between the intermediate unit 101 and the lower unit 103 is the same as that in the first embodiment.

### Maintenance Method

In the substrate processing module 60 according to various embodiments described above, it is possible to remove only one of the units, including the component of the substrate processing module 60 that requires maintenance, and then attach a new corresponding unit. In the present specification, the maintenance includes attaching the substrate processing module 60 in a substrate processing system for the first time, and performing an inspection, cleaning, repair, replacement, or the like.

As an example, a case where maintenance is required for the intermediate unit 101 in the substrate processing modules 60 will be described. First, the upper unit 102 and the lower unit 103 are removed from the main interface unit 70. The removed upper unit 102 and lower unit 103 may be held by a desired bucket, a crane, or the like. Next, the intermediate unit 101 is removed from the main interface unit 70. Next, the removed intermediate unit 101 is transferred from the substrate processing system to the outside. Next, another intermediate unit 101 of the same type as the corresponding unit, which has already been maintained, is transferred from the outside into the substrate processing system. Next, the other intermediate unit 101 is attached to the main interface unit 70. Next, the removed upper unit 102 and lower unit 103 are attached to the main interface unit 70. Thereafter, maintenance may be performed on the removed intermediate unit 101.

The same applies to a case where maintenance is required for the upper unit 102 or the lower unit 103.

According to the maintenance method described above, by removing only one of the units, including the component of the substrate processing module 60 that requires maintenance, and attaching another corresponding unit of the same type, which has already been maintained, the corresponding unit can be replaced. Accordingly, the maintenance of the substrate processing module 60 can be easily and quickly performed, a time when the substrate processing module 60 cannot be used is shortened, and the deterioration in the productivity of the entire substrate processing system can be prevented.

According to the substrate processing module 60 of various embodiments, the power supply lines are provided through the main interface unit 70 and each interface structure. Specifically, as described above, the main interface unit 70 is connected to the power supply lines. The upper interface structure 112 is configured to supply at least one first power from at least one of the power supply lines to the chamber upper wall structure via the main interface unit. The lower interface structure is configured to supply at least one second power from at least one of the power supply lines to the chamber bottom wall structure via the main interface unit.

The power supply lines according to various embodiments include the flow path 211 through which the processing gas supplied from the gas box 80 described above flows, the flow paths 212, 224, and 225 through which the heat transfer fluid or the heat transfer gas for temperature control flows, the coaxial cable 233 for supplying the RF signal to the upper electrode or the lower electrode, the signal cable 206 for supplying a control signal, and the like. In other words, the power from the power supply lines includes at least one selected from the group consisting of electric power that includes the RF signal and the control signal, air, gas, water, and a coolant for driving the apparatus, and the like. In the present disclosure, the term “power supply line” indicates that the line may include not only a configuration for supplying power, but also a configuration for exhausting a gas, a heat transfer fluid, or the like, or outputting a signal.

Accordingly, when the substrate processing module 60 is attached to or removed from the main interface unit 70 for maintenance, operations of attaching and removing various flow paths and cables are concentrated in operations of attaching and removing the substrate processing module 60 to and from the main interface unit 70. As a result, work efficiency is improved at the time of replacement or the like, labor saving and automation of the maintenance can be implemented, and the maintenance can be quickly performed.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art can be obtained from the description herein.

The effects described herein are merely illustrative or exemplary, and are not limited. In other words, the technique according to the present disclosure may have other effects apparent to those skilled in the art from the description herein, in addition to or in place of the effects described above.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

1. A substrate processing system comprising:
a vacuum transfer structure;
a main interface structure having a first surface connected to the vacuum transfer structure, a second surface on a side opposite to the first surface, an upper surface, and a lower surface; and
a substrate processing module, wherein the substrate processing module includes
a replaceable intermediate chamber structure having an upper surface and a lower surface,
a replaceable upper chamber structure detachably connected to the upper surface of the replaceable intermediate chamber structure, and
a replaceable lower chamber structure detachably connected to the lower surface of the replaceable intermediate chamber structure,
the replaceable intermediate chamber structure includes
a chamber sidewall structure defining an interior space,
a substrate support located in the interior space, and
an intermediate interface structure detachably connected to the second surface of the main interface structure,
the replaceable upper chamber structure includes
a chamber upper wall structure defining the interior space and having a gas introduction port to introduce a processing gas into the interior space, and
an upper interface structure detachably connected to the upper surface of the main interface structure, and
the replaceable lower chamber structure includes
a chamber bottom wall structure defining the interior space and having a gas exhaust port to exhaust a gas in the interior space, and
a lower interface structure detachably connected to the lower surface of the main interface structure.

2. The substrate processing system according to claim 1, wherein
the main interface structure is connected to power supply lines,
the upper interface structure is configured to supply at least one first power from at least one of the power supply lines to the chamber upper wall structure via the main interface structure, and
the lower interface structure is configured to supply at least one second power from at least one of the power supply lines to the chamber bottom wall structure via the main interface structure.

3. The substrate processing system according to claim 2, wherein
the at least one first power and the at least one second power include at least one selected from a group consisting of electric power, air, gas, water, and a coolant.

4. The substrate processing system according to claim 3, wherein the gas includes an inert gas.

5. The substrate processing system according to claim 3, wherein
the main interface structure is connected to an exhaust line, and
the upper interface structure is to exhaust the gas in the interior space from the chamber upper wall structure to the exhaust line via the main interface structure.

6. The substrate processing system according to claim 3, wherein
the main interface structure is connected to an exhaust line, and
the lower interface structure is to exhaust the gas in the interior space from the chamber bottom wall structure to the exhaust line via the main interface structure.

7. The substrate processing system according to claim 3, wherein
the substrate processing module includes an exhaust structure to exhaust the gas in the interior space via the chamber bottom wall structure.

8. The substrate processing system according to claim 1, wherein
the substrate processing module includes a gas box structure, and
the processing gas is supplied from the gas box structure into the interior space via the main interface structure and the gas introduction port of the chamber upper wall structure.

9. The substrate processing system according to claim 8, wherein
the gas box structure is attached to a frame of the substrate processing module to be located above the vacuum transfer structure.

10. The substrate processing system according to claim 1, wherein
the substrate processing module includes an electrical circuitry unit configured to control the substrate processing module.

11. The substrate processing system according to claim 10, wherein
the electrical circuitry unit is included in the replaceable upper chamber structure.

12. The substrate processing system according to claim 10, wherein
the electrical circuitry unit is attached to a frame of the substrate processing module to be located above the replaceable upper chamber structure.

13. The substrate processing system according to claim 10, wherein
the substrate support includes an electrostatic chuck, and
the electrical circuitry unit includes a chuck power source configured to apply a chuck voltage to the electrostatic chuck.

14. The substrate processing system according to claim 1, wherein
the substrate processing module includes an RF circuitry unit electrically connected to at least one of the chamber upper wall structure and the chamber bottom wall structure and configured to generate RF power.

15. The substrate processing system according to claim 14, wherein
the RF circuitry unit is included in the replaceable lower chamber structure.

16. The substrate processing system according to claim 14, wherein
the RF circuitry unit is attached to a frame of the substrate processing module to be located below the replaceable lower chamber structure.

17. The substrate processing system according to claim 14, wherein
the RF circuitry unit includes a voltage pulse generator configured to generate a voltage pulse.

18. The substrate processing system according to claim 14, wherein
the substrate support includes an electrostatic chuck, and
the RF circuitry unit includes a chuck power source configured to apply a chuck voltage to the electrostatic chuck.

19. A substrate processing apparatus comprising:
a replaceable intermediate chamber structure having a substrate processing space;
a replaceable upper chamber structure detachably connected to an upper portion of the substrate processing space;
a replaceable lower chamber structure detachably connected to a lower portion of the substrate processing space; and
an interface structure connected to power supply lines, wherein
the interface structure is configured to supply at least one first power from at least one of the power supply lines to the replaceable upper chamber structure via the interface structure, and is configured to supply at least one second power from at least one of the power supply lines to the replaceable lower chamber structure via the interface structure.

20. The substrate processing apparatus according to claim 19, wherein
the at least one first power and the at least one second power include at least one selected from a group consisting of electric power, air, gas, water, and a coolant.
